(19) United States
(12) Patent Application Publication
(10) Pub. No.: US 2005/0151570 A1
(43) Pub. Date: Jul. 14, 2005

(54) Integrated circuit having reduced substate bounce

(76) Inventor: Johannes Petrus Maria Van Lammeren, Nijmegen (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/505,350

(22) PCT Filed: Jan. 27, 2003
(86) PCT No.: PCT/IB03/00282

(30) Foreign Application Priority Data
Feb. 21, 2002 (EP) 02075705.0

(51) Int. Cl. H03L 7/00

(52) U.S. Cl. 327/153

(57) ABSTRACT

A clock strategy is provided for digital circuits inside mixed-signal ICs. An integrated circuit in accordance with the present invention comprises a plurality of pairs of latches (L1, L2) being respectively clocked by two non-overlapping clock signals (Φ1, Φ2). The clock strategy is aimed at keeping the substrate bounce caused by the digital circuits as low as possible. Preferably, not all latches are clocked at the same time, but delays are inserted in the clock lines so that the various latches do not consume current all at the same time. The invention relaxes the demands on the substrate sensitivity of the analog circuits.

The invention relates to integrated circuits and, more specifically, to a reduction of substrate bounce in digital circuits.

One of the major problems of digital circuits is the substrate bounce that they cause. The substrate bounce is a great obstacle when integrating analog circuits in the same IC. But, with the ever increasing speed of digital processes, the currents in the digital circuits have become so high that they even start to affect the local supply (and hence the performance) of the digital circuits themselves.

It is, inter alia, an object of the invention to provide improved integrated circuits. To this end, the invention provides an integrated circuit as defined in the independent claim. Advantageous embodiments are defined in the dependent claims.

These and other aspects of the invention will be apparent from and elucidated with reference to the embodiments described hereinafter.

In the drawings:

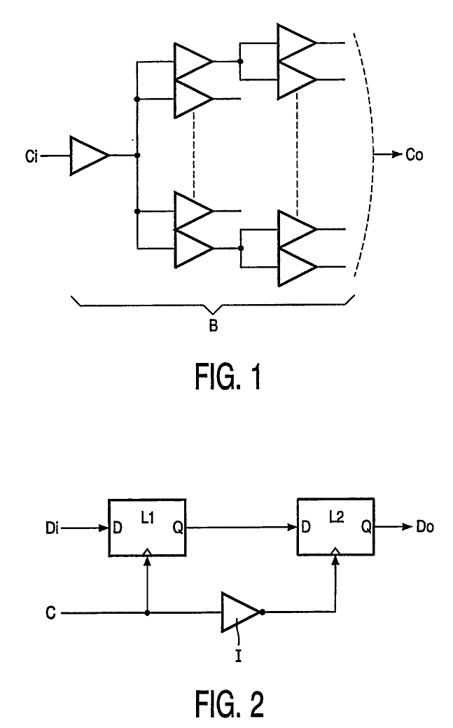

FIG. 1 shows a prior art clock tree;

FIG. 2 shows a prior art edge-triggered flip-flop having two latches;

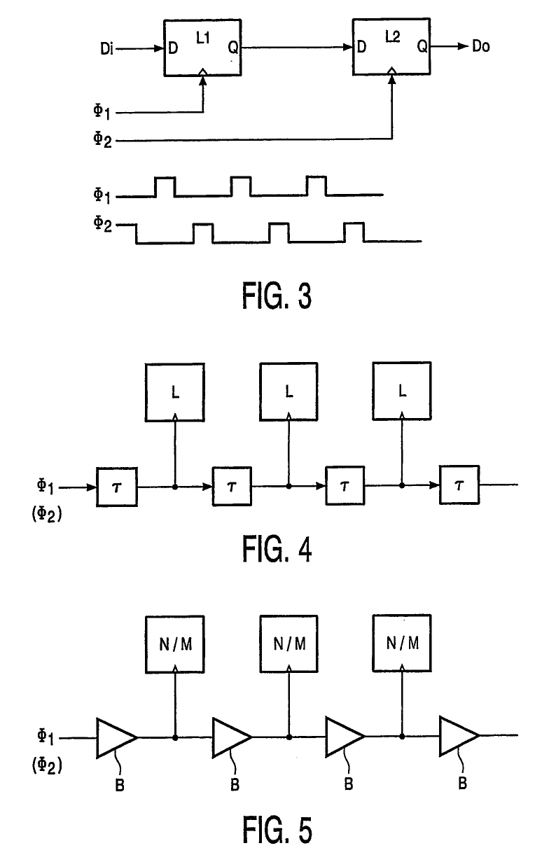

FIG. 3 shows an embodiment of a flip-flip having two latches clocked in accordance with the present invention with two non-overlapping clock phases;

FIG. 4 shows an embodiment of a clock line for non-simultaneous switching of the latches of one of the two clock phases; and

FIG. 5 shows an embodiment of a clock line in which each buffer drives more than one latch.

In many applications, e.g. microprocessors and memories, the maximum speed is absolutely crucial. No compromises on top speed are acceptable if you want to be on the cutting edge in those fields. But there are also fields, e.g. one-chip processors for analog broadcast TV, where top speed of digital circuits is not the number one priority. But, if the digital circuits are not running at their maximum speed to perform their function, this implies they are idling part of the time. This is a waste of resources. The invention is based on the recognition that this time can be used to solve the substrate bounce problem. And, if there is time to spare, in a preferred embodiment of the present invention another highly annoying problem of fast digital circuits is tackled as well: clock skew.

Fast digital circuits usually have a synchronous clock strategy. This means that all flip-flops in the circuit are supposed to switch simultaneously. Using one clock buffer to drive the load of all flip-flops in the circuit is not practical. So, instead of one clock buffer a clock tree is used, as shown in FIG. 1. The clock tree of FIG. 1 has a plurality of buffers B between a clock in Ci and a clock out Co. The clock tree has to be designed in such a way that all buffers B that are connected to flip-flops switch at the same time. This clock strategy has the advantage that the circuits can be extremely fast, but as all flip-flops switch simultaneously, the switching currents are very large. This causes both substrate bounce and momentary drops of the supply voltage (which slows the circuit down). And, even if the clock tree has been designed very carefully, it is hard to guarantee that some flip-flops will not switch later than others under all process/voltage/temperature situations. In other words, avoiding clock skew is a tough and time-consuming job.

FIG. 2 shows the construction of an edge-triggered D flip-flop, the standard memory component of the vast majority of digital circuits. It consists of two latches L1, L2 that are driven from one clock C, but with an inverter I between the two latches' clock inputs. This way the latches L1, L2 are never open at the same time. This construction also means that the input data Di is passed on to the output Do instantly on the active clock edge. But, as the latches are fast but not infinitely fast, they do have so-called set-up and hold tunes. During these short time intervals around the active clock edge the input data is not allowed to change. If it does, the output data of the flip-flop is not reliable. Clock skew occurs when the data of one flip-flop arrives at another flip-flop before the hold time of the second flip-flop has elapsed.

The invention is based on the recognition that clock skew can be avoided by using two non-overlapping clock phases Φ1, Φ2 instead of one (FIG. 3). The skew insensitivity is paid for by a reduction of the maximum clock speed. A wonderful feature of this clock strategy is that if all latches of the same clock phase do not open at the same time, this does not influence the performance of the circuit. If we use this feature to purposely open the latches L1, L2 at different times, we can reduce the peak current that flows in the circuit after a clock transition: the switching current is distributed in time. The fact that the switching current is distributed in time means that the substrate bounce caused by the digital circuit is reduced. How much the reduction is depends on the amount by which the peak current (or better: its dI/dt) is reduced.

FIG. 4 shows how the non-simultaneous switching of the latches can be accomplished: drive the clock input of one latch L from a delay circuit τ connected to another latch L of the same phase Φ1 or Φ2. The digital circuit has two structures like the one shown in FIG. 4: a first structure in which the latches L of FIG. 4 correspond to the latches L1 of FIG. 3 which are clocked by the clock signal having the clock phase Φ1, and a second structure in which the latches L of FIG. 4 correspond to the latches L2 of FIG. 3 which are clocked by the other clock signal having the other clock phase Φ2. The delay circuit τ can simply be a non-inverting buffer. An inverting buffer is smaller, but then two types of latches are needed for each clock phase: active-high and active-low. If the clock inputs of all latches of a circuit having many latches are placed in series like this, the end result will be an extremely slow circuit. So, a compromise has to be found between using one buffer to clock all latches of the same phase in parallel and using as many buffers as there are latches to clock them all in series.

The solution for this is to use a clock line for both clock phases (FIG. 5), in which each node of the clock line drives a number of latches. The number of latches driven by each node in the line is simply N/M, with N being the total number of latches of one clock phase and M being the number of nodes in the clock line. N is determined by the design. M must be chosen such that the clock transient is spread out over the whole clock cycle (in worst case conditions).

To keep the speed of the circuit as high as possible, the latches at inputs of the longest path of the logic should be clocked with the first buffer of the Φ2 clock line. The output of the longest path should be clocked with the last buffer in the Φ1 clock line.

In FIG. 3, Φ1 and Φ2 are drawn as signals with 25% duty cycle and evenly spaced with respect to one another. But, as there is no logic path between the two latches that make up one flip-flop, Φ2 may start immediately after Φ1 closes its last latch. In other words: the clock generator should make Φ2 using the output of the last buffer in the Φ1 clock line as its timing reference.

A preferred embodiment of the present invention can be summarized as follows. A clock strategy is provided for digital circuits inside mixed-signal ICs. An integrated circuit in accordance with the present invention comprises a plurality of pairs of latches L1, L2 being respectively clocked by two non-overlapping clock signals Φ1, Φ2. The clock strategy is aimed at keeping the substrate bounce caused by the digital circuits as low as possible. Preferably, not all latches are clocked at the same time, but delays are inserted in the clock line so that the various latches do not consume current all at the same time. The invention relaxes the demands on the substrate sensitivity of the analog circuits.

The present invention offers the following advantages over the prior art: low substrate bounce, no clock skew, and a design approach that is identical to design approach of “normal” synchronous circuits, i.e. all ‘mainstream’ design tools can be used. At the end of the design process the flip-flops are replaced by double latches and clock lines. The clock control block (used in synchronous digital ICs to prevent clock skew and enter test modes) does not have to take the direction of data flow with respect to the clock into account. The lower substrate bounce can be used to reduce on-chip decoupling. Advantageously, the measure of the present invention does not necessitate a circuit to contain more flip-flops than prior art circuits to obtain a current-pulse-spreading in time. Also, the clock lines do not need to contain more inverters that the prior art clock tree. The advantages of the present invention can thus be obtained without a need for additional circuitry.

It should be noted that the above-mentioned embodiments illustrate rather than limit the invention, and that those skilled in the art will be able to design many alternative embodiments without departing from the scope of the appended claims. The clock signals Φ1, Φ2 do not need to have the same duty cycle. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

1. A integrated circuit comprising:
a plurality of pairs of latches (L1, L2) being respectively clocked by two non-overlapping clock signals (Φ1, Φ2).

2. A integrated circuit as claimed in claim 1, wherein delay circuits (τ) are placed between clock inputs of latches (L) of a same clock phase (Φ1 or Φ2).

3. A integrated circuit as claimed in claim 2, wherein each delay circuit (B) drives more than one latch.
